(19) United States
(12) Patent Application Publication
(10) Pub. No.: US 2021/0220963 A1
(43) Pub. Date: Jul. 22, 2021

(54) ROTOR DISK AND DOUBLE-SIDED PROCESSING MACHINE FOR PROCESSING AT LEAST ONE WORKPIECE AND ASSOCIATED METHOD

(71) Applicant: Lapmaster Wolters GmbH, Rendsburg (DE)

(72) Inventors: Helge Möller, Flensburg (DE); Jörn Kanzow, Kiel (DE)

(73) Assignee: Lapmaster Wolters GmbH, Rendsburg (DE)

(21) Appl. No.: 17/154,424

(22) Filed: Jan. 21, 2021

(30) Foreign Application Priority Data
Jan. 21, 2020 (DE) 10 2020 101 313.2

(51) Int. Cl. B24B 37/08

(52) U.S. Cl. CPC B24B 37/08

(57) ABSTRACT

A rotor disk for guiding workpieces in a double-sided processing machine including a fluid feeding apparatus to feed a processing fluid into a working gap between a first working disk and a second working disk is provided. The rotor disk comprises a surface defining at least one workpiece opening configured to receive at least one workpiece to be processed on both sides in the double-sided processing machine in a material-removing manner using the processing fluid. A contact angle of a drop of the processing fluid with the surface is at least 60°.

### CROSS REFERENCE TO RELATED INVENTION

This application is based upon and claims priority to, under relevant sections of 35 U.S.C. § 119, German Patent Application No. 10 2020 101 313.2, filed Jan. 21, 2020, the entire contents of which are hereby incorporated by reference.

### TECHNICAL FIELD

The invention relates to a rotor disk for guiding workpieces in a double-sided processing machine that comprises at least one workpiece opening for receiving at least one workpiece to be processed in a material-removing manner on both sides in the double-sided processing machine. In addition, the invention relates to a double-sided processing machine and a method for processing at least one workpiece in a double-sided processing machine.

### BACKGROUND

Workpieces, such as wafers, are guided in double-sided processing machines, for example double-sided polishing machines, in rotor disks for processing. The rotor disks generally have multiple workpiece openings, in which the workpieces to be processed are received in a floating manner. During operation, the rotor disks are arranged between the working disks of the double-sided processing machine in the working gap formed by the working disks. In the course of the relative rotation between the working disks, the rotor disks are, on the one hand, rotated along a circular path through the working gap and, on the other hand, about their own axis. As a result, the workpieces held in a floating manner in the rotor disks move along cycloid tracks through the working gap. The aim of this movement is to bring about a material-removing processing which is as uniform as possible and, consequently, to achieve a particularly high plane parallelism and flatness of the processed workpieces. For the material-removing processing, a processing fluid, in particular a so-called slurry, is generally introduced into the working gap. Said processing fluid can contain abrasive constituents.

Semiconductor wafers processed in such double-sided processing machines are in particular used to form integrated circuits (IC). Since the structures of integrated circuits are becoming smaller and smaller, it is crucial that various geometry parameters are observed in the best possible manner during the manufacture of semiconductor wafers, by way of example made of silicon. In particular, the thickness dispersion over the entire workpiece is to be minimal and the flatness at the edge of the workpiece is to be maximized. In addition, the wear of the rotor disks is to be minimized.

The rotor disks and processing methods which have been utilized up to now lead to a significant rounding of the workpieces in the edge or respectively marginal region. In addition, common rotor disks are subject to considerable wear. In DE 10 2017 221931 A1, a rotor disk having a DLC (diamond-like-carbon) coating and a hydrophilic surface with a contact angle of a water drop of less than 25° is proposed in order to increase the wear resistance and to improve the edge geometry. In practice, however, these measures do not lead to a sufficient increase in the wear resistance and a sufficiently improved edge geometry of the workpieces.

Starting from the explained prior art, the object of the invention is therefore to provide a rotor disk, a double-sided processing machine and a method of the type indicated above, with which it is possible to further optimize the edge geometry of the workpieces and to further reduce the wear of the rotor disks in particular.

### BRIEF SUMMARY OF THE INVENTION

For a rotor disk of the type indicated above, the invention achieves the object in that the surface of the rotor disk includes a contact angle of a water drop or a drop of processing fluid of at least 60°.

In addition, the invention achieves the object through a double-sided processing machine, comprising a first working disk having a first working surface and a second working disk having a second working surface, wherein the working surfaces delimit between them a working gap, and wherein at least one of the working disks of the double-sided processing machine can be rotatingly driven. A fluid feed is provided for feeding a processing fluid into the working gap, and comprising at least one rotor disk according to the invention, with which at least one workpiece can be guided in the working gap for material-removing processing on both sides.

In addition, the invention achieves the object through a method for processing at least one workpiece in a double-sided processing machine according to the invention, in which the at least one workpiece is received in the at least one workpiece opening of the at least one rotor disk and is guided for processing in the working gap of the double-sided processing machine, wherein at least one of the working disks of the double-sided processing machine is rotatingly driven, and wherein a processing fluid is fed into the working gap during the processing.

The double-sided processing machine can, for example, be a double-sided polishing machine. A rotor disk usually comprises multiple workpiece openings. As explained above, workpieces such as wafers, in particular semiconductor wafers, by way of example made of silicon, are held in a floating manner in workpiece openings of rotor disks. During operation, the rotor disks are arranged in the working gap between the opposite working disks of the double-sided processing machine. The rotor disks generally have outer teeth which are in mesh with inner teeth, which are provided on the inner edge of the working gap, and with outer teeth, which are provided on the outer edge of the working disk, of the double-sided processing machine, for example the lower working disk. In the course of the rotation which occurs during operation of at least one working disk, the rotor disk is as a result rotated, on the one hand, along a circular path through the working gap and, on the other hand, about its own axis. The workpieces received in the workpiece openings of the rotor disks are, as a result, guided in the known way along cycloid tracks through the workpiece and processed in a material-removing manner. Likewise, a processing fluid, by way of example a so-called slurry, is introduced into the working gap in the known way during the processing. The processing fluid can contain abrasive elements.

According to the invention, the surface of the rotor disk includes a contact angle of a water drop of at least 60°. That is to say that, in contrast to the prior art explained above, the surface is not hydrophilic. The surface of the rotor disk can, according to the invention, include a contact angle of a water drop of preferably at least 65°, more preferably at least 70°. The inventors have realized that, in the prior art, a non-optimum distribution of the processing fluid on the surface of the rotor disk and, therefore, on the processed workpieces leads to increased wear of the rotor disk and a non-optimum edge geometry of the processed workpieces. In particular, the present inventors have realized that, in the prior art, a non-homogeneous film of fluid occurs between the processed workpiece and the surface of the working disks, for example a polishing cloth, in particular a decrease in the thickness of the film of fluid from the edge to the middle of the processed workpiece, so that a non-uniform material removal is effected, which, in turn, leads to the unwanted reinforced edge rounding of the workpiece. This is countered by the surface design according to the invention of the rotor disk. Due to the configuration according to the invention of the surface of the rotor disk, a more homogeneous film of fluid on the rotor disk and, therefore, also on the processed workpiece is achieved, compared with the prior art. In particular, the transport of the processing fluid, in particular the polishing fluid, to the middle of the workpiece is considerably improved by the configuration according to the invention of the rotor disk surface. In this way, the unwanted edge rounding of the workpiece that occurs in the prior art is minimized. All in all, the geometry of the processed workpieces is thus improved. At the same time, the homogenization of the film of fluid according to the invention minimizes the wear of the rotor disks, extends the lifetime and leads to corresponding cost advantages. The present inventors have realized that, despite this being proposed in DE 10 2017 221931 A1, no hydrophilic surface is in actual fact expedient for this purpose but, on the contrary, a non-hydrophilic or respectively even a hydrophobic surface is expedient. The rotor disk according to the invention can, by way of example, consist of a metallic material such as, by way of example, stainless steel.

According to a configuration, the surface of the rotor disk includes a contact angle of a water drop of not more than 90°, preferably of not more than 75°. The inventors have further realized that, in particular above 90°, a reinforced edge rounding of the workpiece occurs again. That is to say, there exists an optimum window for the contact angle, in which the edge rounding is minimized.

According to a further embodiment, the desired contact angle of the surface according to the invention can be obtained by roughening the surface of the rotor disk. That is to say that the desired contact angle is then adjusted mechanically, by way of example by a corresponding double-sided processing process for the rotor disks. Correspondingly roughened rotor disks can then remain without any further coating. In particular, a metallic material, by way of example stainless steel, is possible as a material for the roughened rotor disks.

It is also possible to achieve the surface with the desired contact angle by selecting a suitable rotor disk material, if necessary without an additional coating or roughening measures. By way of example, a metallic material such as, by way of example, stainless steel is possible as a rotor disk material.

It is also possible to achieve the desired contact angle of the surface by a suitable coating of a rotor disk base material. For example, it is possible to adjust the contact angle according to the invention by a suitable DLC coating, wherein further processing such as roughening does not then have to be effected. By way of example, a metal such as, by way of example, stainless steel, can be utilized as a rotor disk base material.

In an embodiment, the rotor disk can, in addition to the at least one workpiece opening, may define or include at least one auxiliary opening, in which a processing fluid, preferably a polishing fluid such as a slurry, can collect during processing of the at least one workpiece in the double-sided processing machine. In an embodiment, the rotor disk can in particular include multiple workpiece openings and/or multiple auxiliary openings. Due to the targeted provision of one or more auxiliary openings, the effect according to the invention of homogenizing the film of processing fluid can be further reinforced. It has been shown that processing fluid situated in the auxiliary openings evens out the film of fluid over the entire surface of the rotor disk and, therefore, also over the surface of the processed workpiece. On the one hand, a more uniform fluid distribution is achieved on the upper side and lower side of the rotor disk through the auxiliary openings, in which no workpiece to be processed is received during operation, since the processing fluid can escape relatively freely through the auxiliary openings. On the other hand, the fluid transport from the outer region of the rotor disks, in particular the region of the outer teeth, to the workpieces and to the middle of the rotor disk is improved by the auxiliary openings. In this way, the processing result can be further optimized and the wear of the rotor disks can be further minimized. The auxiliary openings can in particular be formed between the workpiece openings. For example, multiple auxiliary openings can in each case be formed between two neighboring workpiece openings. This further improves the fluid distribution.

### BRIEF DESCRIPTION OF THE DRAWINGS

Exemplary embodiments of the invention will be explained in greater detail below with reference to figures, wherein:

FIG. 1 illustrates a cross-sectional view of a schematic depiction of an embodiment of a double-sided processing machine;

FIG. 2 illustrates a top plan view of a schematic depiction of an embodiment of a rotor disk of an embodiment of the double-sided processing machine;

FIG. 3 illustrates a top plan view of a schematic depiction of another embodiment of a rotor disk of an embodiment of the double-sided processing machine; and

FIG. 4 illustrates a diagram showing average thickness profiles of different workpieces subjected to double-sided processing in a material-removing manner.

Unless otherwise indicated, the same reference numerals denote the same objects in the figures.

### DETAILED DESCRIPTION OF THE INVENTION

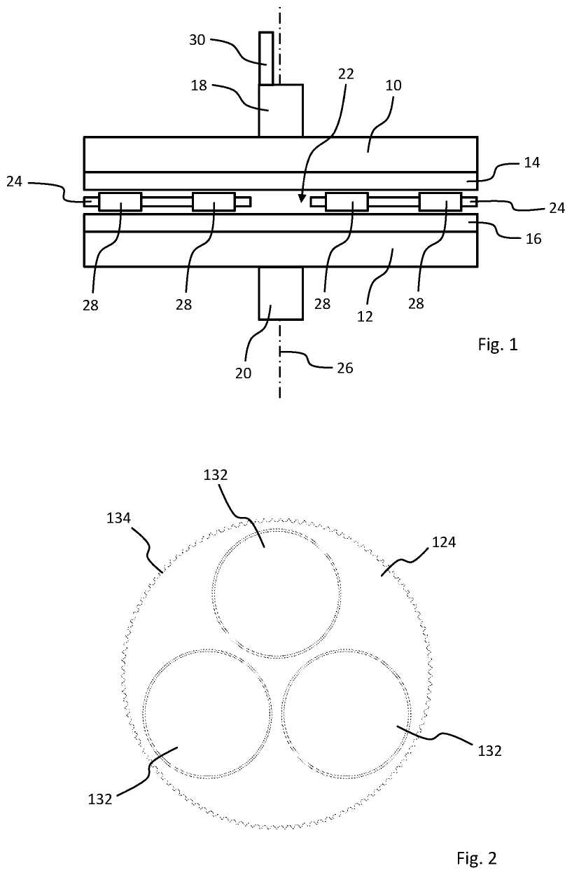

In FIG. 1, a double-sided processing machine according to the invention, in particular a double-sided polishing machine, is depicted schematically. The double-sided processing machine includes an upper carrier disk 10 and a lower carrier disk 12 arranged opposite the upper carrier disk 10. The upper carrier disk 10 carries an upper working disk 14 and the lower carrier disk 12 carries a lower working disk 16. The working disks 14, 16 can, by way of example, be provided with a polishing covering, in particular a polishing pad. The carrier disks 10, 12 and, with them, the working disks 14, 16 can be rotatingly driven around their axis 26 which runs vertically in FIG. 1 by way of drive shafts 18, 20, in particular in opposite directions during operation of the double-sided processing machine.

The working disks 14, 16 delimit between them a working gap 22. Multiple rotor disks 24 are arranged in the working gap. In FIG. 1, two rotor disks 24 are depicted. Of course, more or less than two rotor disks can also be provided. Workpieces 28, for example semiconductor wafers, for example made of silicon, which are to be processed in a material-removing manner on both sides, are held in a floating manner in the workpiece openings of the rotor disks 24 in the working gap 22. The rotor disks 24 usually have, at their outer edge, outer teeth which are not depicted in greater detail in FIG. 1 which are in mesh with inner teeth which are arranged on the inner edge of the working gap 22, which are not depicted in greater detail in FIG. 1, as well as outer teeth which are arranged on the outer edge of the working gap 22, which are likewise not depicted in greater detail in FIG. 1. As a result, the rotor disks 24 are rotated along a circular path through the working gap 22 and additionally about their axes during operation, so that the workpieces 28 move along cycloid tracks through the working gap 22. By means of a fluid feed which is depicted schematically in FIG. 1 with the reference numeral 30, a processing fluid, in particular a polishing fluid (slurry) is fed into the working gap 22 during operation. The surface of the rotor disks 24 has a contact angle of a water drop of at least 60°. For example, the surface of the rotor disk 24 can be mechanically roughened in order to achieve said contact angle. The surface of the rotor disk 24, which can consist by way of example of stainless steel, can, alternatively or additionally to roughening, also be provided with a coating, for example a DLC coating, in order to achieve the desired contact angle.

In FIG. 2, a further rotor disk 124 according to the invention is shown, which can be utilized in the double-sided processing machine shown in FIG. 1. The rotor disk 124 has, in the example shown, three circular workpiece openings 132, in which workpieces for processing can be received in a floating manner. In addition, the outer teeth 134 can be seen in the case of the rotor disk 124 in FIG. 2. The rotor disk 124 shown in FIG. 2 also has a contact angle of a water drop of at least 60°. For example, the surface of the rotor disk 124 can be mechanically roughened in order to achieve said contact angle. The surface of the rotor disk 124, which can consist by way of example of stainless steel, can also, alternatively or additionally to roughening, be provided with a coating, for example a DLC coating, in order to achieve the desired contact angle.

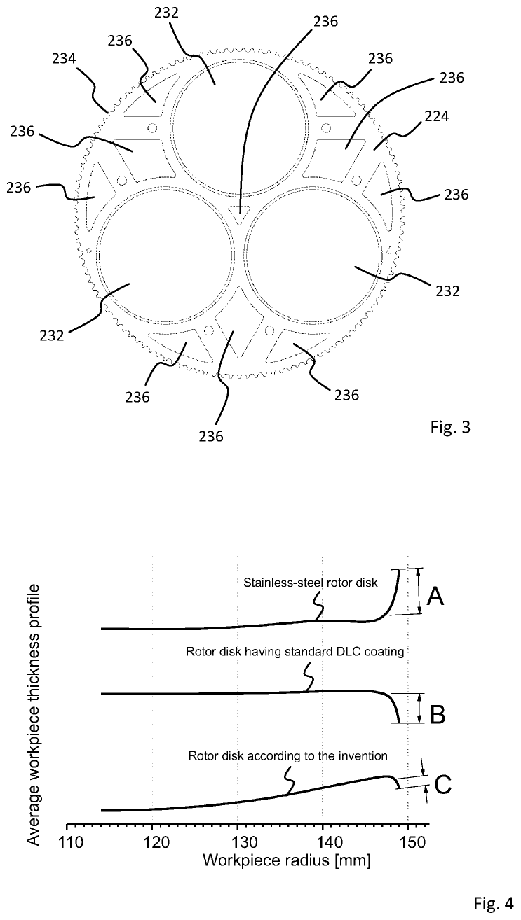

FIG. 3 shows a further exemplary embodiment of a rotor disk 224 which can likewise be utilized in the double-sided processing machine shown in FIG. 1. As shown, the rotor disk 224 defines three circular workpiece openings 232 for receiving workpieces to be processed in a floating manner as well as outer teeth 234. Unlike the rotor disk 124 shown in FIG. 2, the rotor disk 224 shown in FIG. 3 has, in addition to the three workpiece openings 232, multiple auxiliary openings 236. The fed processing fluid can collect in the auxiliary openings 236 during the processing of the workpieces in the working gap 22 of the double-sided processing machine. The auxiliary openings 236 serve as a reservoir for processing fluid and lead to an optimum homogenization of the film of fluid on the rotor disk 224 and, indeed, on the upper and lower side and on the individual sides, and therefore also on the workpieces received in the workpiece openings 232. The rotor disk 224 shown in FIG. 3 also has a contact angle of a water drop of at least 60°. For example, the surface of the rotor disk 224 can be mechanically roughened in order to achieve said contact angle. The surface of the rotor disk 224, which can by way of example comprise of stainless steel, can, alternatively or additionally to roughening, also be provided with a coating, for example a DLC coating, in order to achieve the desired contact angle.

All or some of the rotor disks 24, 124, 224 shown in FIGS. 1-3 can include a contact angle of a water drop of preferably not more than 90°, more preferably not more than 75°. In addition, they can include a contact angle of a water drop of preferably at least 65°, more preferably at least 70°. They can, for example, be comprised of stainless steel or respectively include stainless steel as a base material during a subsequent coating. They can, however, also be comprised of other materials. It is also conceivable that the rotor disks 24, 124, 224 are comprised of a material which already intrinsically has the desired contact angle, so that no subsequent coating or roughening is required. If the surface of the rotor disks 24, 124, 224 is roughened, or if the rotor disk material already intrinsically has the desired contact angle, it is possible that these do not have any further coating.

In FIG. 4, an average workpiece thickness profile for workpieces processed with three different rotor disks, in particular silicon wafers, is depicted. The outer workpiece region as of a workpiece radius of approximately 114 mm up to the outer workpiece edge at approximately 149 mm is shown. The basic thickness in particular in the region of the workpiece middle, which can be seen in FIG. 4 for instance with the workpiece radius 114 mm, can be substantially equal or respectively standardized for all workpieces. The curves are merely depicted above one another in FIG. 4 for illustration purposes. The average workpiece thickness profiles have been established by processing in each case of a multiplicity of workpieces with one of the three rotor disks and subsequent averaging of the thickness profile. The processing was effected in the example shown in a double-sided polishing machine belonging to the applicant, wherein a polishing fluid (slurry) was fed into the working gap during the processing.

The top curve in FIG. 4 shows the average workpiece thickness profile when a plain uncoated stainless-steel rotor disk was used. The middle curve in FIG. 4 shows the average workpiece thickness profile when a stainless-steel rotor disk having a usual DLC coating was used. The bottom curve in FIG. 4 shows the average workpiece thickness profile using a rotor disk according to the invention having a contact angle of the surface for a water drop of at least 60°.

In FIG. 4, the height of the edge rounding of the workpiece thickness profiles is drawn in, in each case, for the letters A, B and C. It can be clearly seen that the edge rounding A is greatest when the stainless-steel rotor disk is used, followed by the edge rounding B when a rotor disk having a usual DLC coating is used. By contrast, a considerably lower edge rounding C is attained with the rotor disk according to the invention.

List of reference numerals

| | |
|---|---|
| Upper carrier disk | 10 |
| Lower carrier disk | 12 |
| Upper working disk | 14 |
| Lower working disk | 16 |
| Drive shaft | 18 |
| Drive shaft | 20 |
| Working gap | 22 |
| Rotor disk | 24 |
| Axis | 26 |
| Workpiece | 28 |
| Fluid feeding apparatus | 30 |
| Rotor disk | 124 |
| Workpiece opening | 132 |
| Outer teeth | 134 |
| Rotor disk | 224 |
| Workpiece opening | 232 |
| Outer teeth | 234 |
| Auxiliary opening | 236 |

1. A rotor disk for guiding workpieces in a double-sided processing machine including a fluid feeding apparatus to feed a processing fluid into a working gap between a first working disk and a second working disk, the rotor disk comprising:
a surface defining at least one workpiece opening configured to receive at least one workpiece to be processed on both sides in the double-sided processing machine in a material-removing manner using the processing fluid, wherein a contact angle of a drop of the processing fluid with the surface is at least 60°.

2. The rotor disk according to claim 1, wherein the contact angle of the drop of the processing fluid is not more than 90°.

3. The rotor disk according to claim 1, wherein the contact angle of the drop of the processing fluid is not more than 75°.

4. The rotor disk according to claim 1, wherein the surface of the rotor disk is roughened.

5. The rotor disk according to claim 1, wherein the surface of the rotor disk is covered with a coating.

6. The rotor disk according to claim 5, wherein the coating is a DLC coating.

7. A double-sided processing machine comprising:
a first working disk comprising a first working surface;
a second working disk comprising a second working surface, wherein the first and second working surfaces delimit a working gap between them, and wherein at least one of the first working disk and the second working disk is configured to be rotatingly driven;
a fluid feed configured to feed a processing fluid into the working gap; and
at least one rotor disk comprising a surface that defines at least one workpiece opening configured to receive at least one workpiece to be processed on both sides in a material-removing manner using the processing fluid, wherein a contact angle of a drop of the processing fluid with the surface of the rotor disk is at least 60°.

8. The double-sided processing machine according to claim 7, wherein the at least one workpiece is received in the at least one workpiece opening of the at least one rotor disk and is guided for processing in the working gap of the double-sided processing machine.

9. The double-sided processing machine according to claim 8, wherein at least one of the first working disk and the second working disk is rotatingly driven, and wherein the processing fluid is fed into the working gap during processing.
